(19) United States
(12) Patent Application Publication
(10) Pub. No.: US 2007/0296513 A1
(43) Pub. Date: Dec. 27, 2007

(54) Oscillator

(76) Inventors: Werner Ruile, Munich (DE); Edgar Schmidhammer, Stein (DE)

Correspondence Address: FISH & RICHARDSON PC, P.O. BOX 1022, MINNEAPOLIS, MN, 55440-1022, US

(21) Appl. No.: 11/628,854

(22) PCT Filed: May 10, 2005
(86) PCT No.: PCT/EP05/05055

§ 371 Date: Jul. 19, 2007

(30) Foreign Application Priority Data
Jun. 9, 2004 (DE) 102004028968.1

(51) Int. Cl. H03B 5/18; H03B 5/24; H03B 5/30; H03B 5/32

(52) U.S. Cl. 331/116 R; 331/108 R; 331/117 R

(57) ABSTRACT

The invention pertains to an oscillator with a resonator element and a control element for adjusting the resonant frequency of the resonator element to a plurality of different values, wherein the resonator element consists of at least one resonator. The control element can be realized as a control layer for controlling the propagation speed of the acoustic wave in the resonator. The control element can alternatively be constructed as a switch element and be used for switching different sub-branches of a resonator element constructed as a resonator magazine or a resonator bank. A trimming element, with which fine-tuning of the oscillator frequency is possible, is preferably also provided.

The invention pertains to an oscillator, in particular, an oscillator with a resonator in its feedback branch.

Oscillators with an electrical resonator (thick-film or thin-film resonator), the dielectric or piezoelectric film of which consists of quartz, are generally known. The quartz oscillators generate a signal with a frequency that is stable to a large extent, which lies between 10 kHz and 200 MHz.

An oscillator in which a thin-film resonator is arranged in the feedback branch of a transistor is known from the publication, B. Otis and J. Rabaey, “A 300 μW 1.9-GHz CMOS Oscillator Utilizing Micromachined Resonators,” IEEE 2003, p. 1271. This oscillator generates an HF (high frequency) signal at 1.9 GHz. This signal can be employed as the reference frequency of a modulator in a portable radio set, for example.

The oscillator oscillates at a frequency that lies between the resonant frequency and the antiresonant frequency of the resonator. An adjustment of the oscillator frequency can be accomplished inside this interval with, for instance, a trimming capacitor. The difference between the resonant frequency and the antiresonant frequency, conditional upon the properties of the piezoelectric film, is ca. 1-3% in relation to the center frequency. Therefore only a slight adjustment of the oscillator frequency is possible.

The use of a digitally controlled capacitor bank in a feedback branch of a CMOS-based Pierce oscillator is known from the publication, Qiuting Huang and P. Basedeau, “Design Considerations for High-Frequency Crystal Oscillators Digitally Trimmable to Sub-ppm Accuracy,” IEEE 1997, p. 408, FIG. 7. The capacitor bank can be connected in parallel to a quartz resonator.

Depending on the application, oscillators are also required for another frequency, for instance, >2 GHz. In individual cases, the oscillator frequency can be adjusted by, for instance, adjusting the resonant frequency of a thin-film resonator by means of an appropriate thickness of the piezoelectric film, for example. A subsequent matching of the frequency in another component is not possible, however.

The problem of the present invention is to specify an oscillator with high quality, the frequency of which is externally adjustable independently of design.

This problem is solved according to the present invention by an oscillator with the characteristics of Claim 1. Advantageous configurations of the invention can be deduced from additional claims.

The invention specifies an oscillator with a resonator element that has an adjustable resonant frequency and a control element for adjusting the resonant frequency of the resonator to various values. The resonator element consists of at least one resonator.

With a control element it is possible, by controlling the frequency of the resonator element, to achieve a shift of the oscillator frequency that exceeds the distance from the resonant to the antiresonant frequency of an individual resonator. A trimming element, on the other hand, changes the oscillator frequency without also shifting the frequency of the resonator element. The control element on its own is therefore not a trimming element whose electrical values, particularly the impedance parameters such as capacitance or inductance, are adjustable. In the sense of the invention, the resonator element on its own represents a trimming element or a (preferably externally) controllable “trimming resonator.” The invention therefore has the advantage that a highly precise adjustment of an oscillator frequency in a wide-band frequency interval is possible with a resonator element and a control element. The oscillator of the invention is distinguished by low phase noise.

The oscillator of the invention is preferably provided for the generation of oscillations with a frequency of ca. 1 GHz and up. The oscillator can have any basic circuitry (e.g., Pierce oscillator, Colpitts oscillator) with at least one amplifier element. The amplifier element can be a CMOS (complementary metal oxide semiconductor) operational amplifier or a field-effect transistor.

The oscillator has an oscillator circuit that comprises an amplifier element and a resonant circuit with a resonator element. The resonant circuit is arranged in a branch that is, for instance, a feedback branch of the amplifier element. The resonant circuit can also be arranged between the input of the amplifier element and ground.

In principle, the resonator can be a dielectric resonator. Alternatively, the resonator can be constructed in strip-line technology. The resonator can also be an LC resonator. The formation of the resonator as a micromechanical element is also possible.

The resonator is preferably an electroacoustic resonator (i.e., one operating with acoustic waves). The electroacoustic resonator preferably has a piezoelectric film.

In one variant of the invention, the resonator can be a thin-film resonator (FBAR=Thin Film Bulk Acoustic Wave Resonator) that has at least one piezoelectric film arranged between two electrodes. The thin-film resonator can be a membrane-type resonator arranged over a cavity on a substrate. The thin-film resonator can be a resonator arranged over an acoustic mirror on a substrate. The thin-film resonator can be a resonator stack with several acoustically and/or electrically coupled (component) resonators arranged one on top of the other. The coupled resonators can be coupled only acoustically, via a coupling layer.

In another variant, the resonator can be a resonator operating with surface waves, such as a DMS resonator (DMS=double mode SAW, SAW=surface acoustic wave) with transducers acoustically coupled longitudinally, or a one-gate resonator. A SAW resonator can be formed as a thin film SAW component in which the piezoelectric film is produced in thin-film technology.

The desired frequency shift is done by an appropriate driving of the control element associated with the resonator or resonator element. The control element is preferably electrically driven, preferably by a control voltage.

In a first preferred variant of the invention, the resonator element is constructed as a resonator magazine or a resonator bank. The resonator bank comprises several resonators. The different resonators preferably have differing resonant frequencies.

The entire broadband, fully tunable frequency interval is subdivided into different narrow-band subranges (frequency ranges). This has the advantage that the phase noise can be kept low in a narrow-band frequency range. Each frequency range is associated with a resonator of its own.

A selector switch or switching elements connect (preferably exactly) one resonator to the amplifier element of the oscillator. The selector switch or the switching elements represent a control element. The selector switch can be available as a finished component that is suited to select between two or more sub-paths.

The resonators are preferably arranged in sub-branches of a resonant circuit connected to one another in parallel. The sub-branches are switched on by the corresponding control element in the resonant circuit. One sub-branch is preferably associated with one switching element or one terminal of a selector switch. The switching element is preferably connected electrically in series to the corresponding resonator.

At a given time, or in a certain frequency range, at least one resonator—preferably only one resonator—is switched into the resonant circuit. In case of switching between different resonators, the resonant frequency of the resonator, and therefore the oscillator frequency as well, changes stepwise. For fine-tuning the oscillator inside a frequency range, a trimming element, e.g. a trimming capacitor or a trimming inductor, is preferably provided. It is possible to construct a trimming capacitor as a switchable capacitor bank, preferably digitally controlled. The capacitor bank can consist, for instance, of CMOS capacitors. The trimming capacitor can also be realized as a varactor or “switched capacitor.” Additional trimming elements are also possible.

In case of multiple turned-on resonators that have different resonant frequencies, multiple signals with different frequencies can be generated simultaneously in the oscillator.

The resonator bank can be constructed of separate resonators. Preferably, however, all resonators are formed on a common substrate. The resonator bank can be formed as a chip. In one variant it is possible to form a chip with a switchable resonator bank. The control element and the resonator element, i.e., several resonators, are components of the switchable resonator bank in this case. The chip can comprise additional components, particularly the components of the oscillator (e.g., an amplifier element, switching elements, trimming elements for fine-tuning the oscillator frequency, L, C, R). Alternatively, the chip with the resonator bank or the switchable resonator bank can be mounted on a carrier substrate on which the additional components of the oscillator are arranged. The chip can be connected to the carrier substrate by means of bonding wires or in flip-chip technology. The control elements can also be formed as one chip each or together as a chip.

The carrier substrate can have several metal layers connected to one another via vertical electrical connections, and interposed dielectric layers, with structures of the oscillator circuit formed in the metal layers (preferably in the hidden metal layers).

The switch elements arranged in the component branches can be available together in one chip and constitute a switch bank. It is also possible to construct the switch elements independently of one another. The switch elements can be semiconductor elements or micromechanical switches (MEMS).

In a second preferred variant of the invention, the resonator element arranged in the resonant circuit of the oscillator is a resonator that is constructed such that its resonant frequency is adjustable by a physical—optionally, mechanical or thermal—effect, for example, as a result of a deformation of the piezoelectric layer induced by pressure or tension. A combination of different types of effects, e.g., mechanical and thermal, is also possible.

In this case the control element is preferably solidly connected to the piezoelectric layer of the resonator. The control element can be realized as, for instance, a control layer for controlling the propagation velocity of the acoustic wave in the piezoelectric layer of the resonator. A stepless tuning of the resonant frequency of the resonator is also possible.

A control layer can be formed as a composite of a first and second control layer. The first control layer is in contact with the piezoelectric layer of the resonator, and serves to modify the propagation velocity of the acoustic wave in the piezoelectric layer of the resonator. The second control layer preferably serves to create mechanical tensions in the first control layer. The second control layer is preferably formed as a piezoelectric control layer.

A trimming element with which an independent (additional) fine tuning is possible can be provided in the second preferred variant as well. This embodiment is particularly space-saving in relation to the footprint of the arrangement.

The two preferred variants of the invention can be combined with one another. In particular, the resonator bank can have several tunable resonators.

Current-controlled or voltage-controlled switches (e.g., GaAs switches) can be provided as switch elements. The switch elements can be semiconductor switches such as diodes, transistors (particularly field-effect transistors) or MEMS switches. The combination of the various above-mentioned structures in one switch element or selector switch is also possible.

The invention will be described in detail below on the basis of embodiments and associated figures. The figures show various embodiments of the invention on the basis of schematic representations not drawn to scale. Identical or identically-acting parts are labeled with identical reference characters. Shown schematically are:

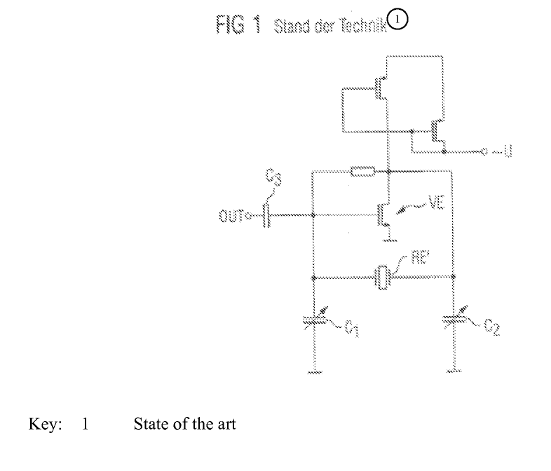

FIG. 1, a known Pierce oscillator with a resonator in the feedback branch of an amplifier;

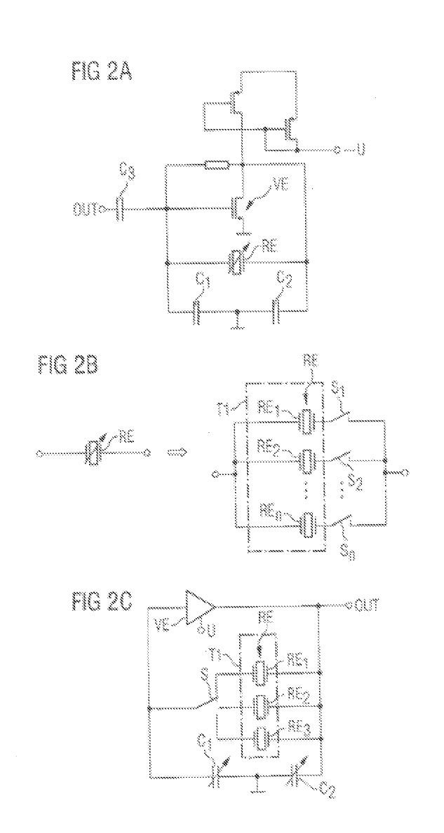

FIG. 2A, an oscillator according to the invention with a tunable resonator as resonator element;

FIG. 2B, an embodiment of a tunable resonator as a resonator bank, the resonators of which are each inserted into sub-branches of a resonant circuit;

FIG. 2C, an oscillator with an operational amplifier as amplifier element, a resonator bank and a selector switch;

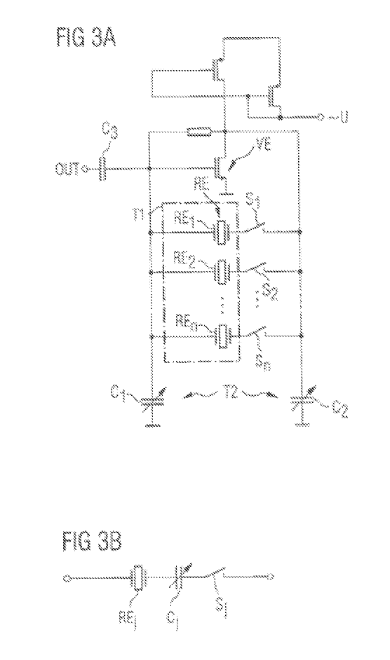

FIG. 3A, a resonator according to the invention with a field-effect transistor as amplifier element, a resonator bank and switch elements in the sub-branches of the resonant circuit;

FIG. 3B, a sub-branch of the resonator circuit with several sub-branches, wherein the sub-branch has a trimming capacitor;

FIG. 4, the resonance curves of various resonators in a resonator bank;

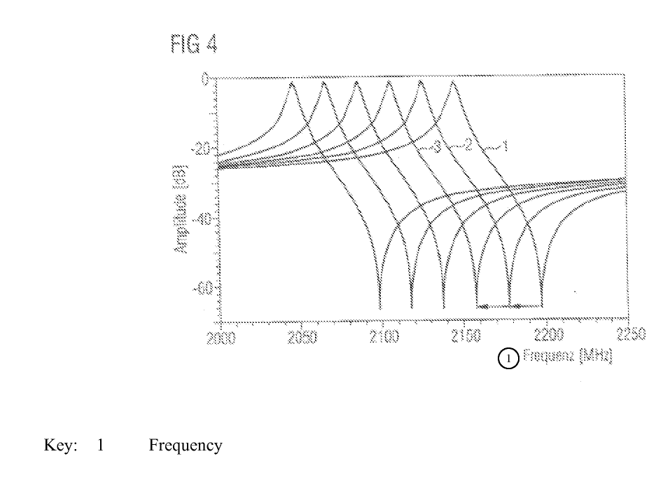

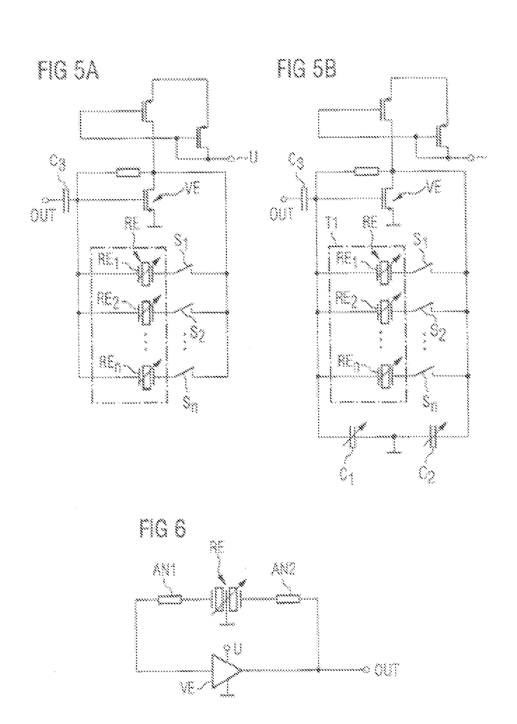

FIG. 5A, an oscillator with a resonator bank that consists of tunable resonators (without trimming capacitors);

FIG. 5B, an oscillator with a resonator bank that consists of tunable resonators, and with trimming capacitors;

FIG. 6, an oscillator with a tunable resonator filter that has acoustically-coupled component resonators;

FIG. 7, an oscillator according to FIG. 3A, in which the control elements in the sub-branches are voltage-controlled switch elements;

FIG. 8, an oscillator according to FIG. 7, in which the trimming capacitor is a capacitor bank;

FIG. 9, a tunable thin-film resonator with a control layer;

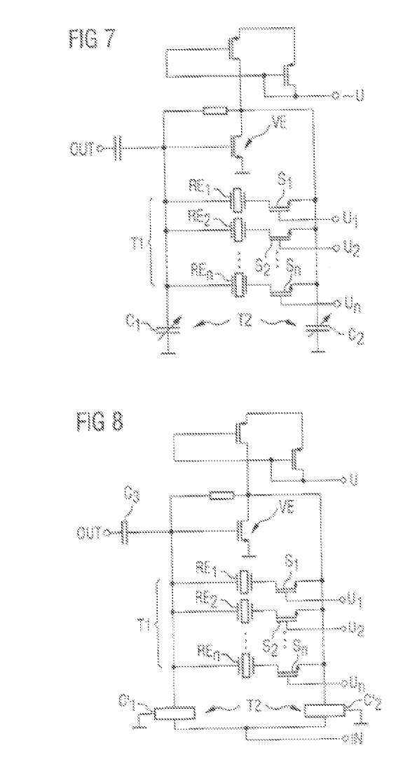

FIG. 10, a tunable thin-film resonator in which the control element comprises two control layers;

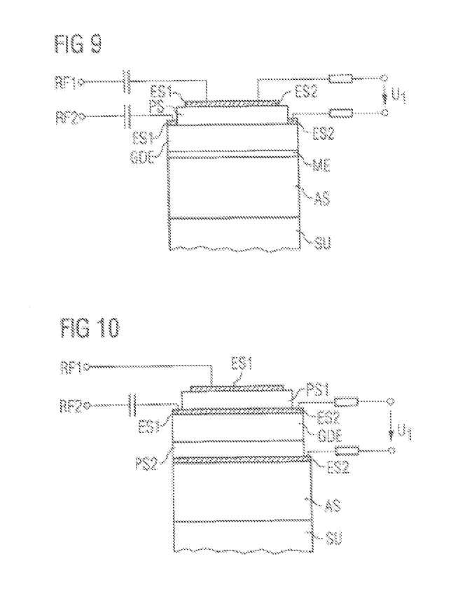

FIG. 11, a tunable surface wave filter as a resonator element in which a control layer is provided;

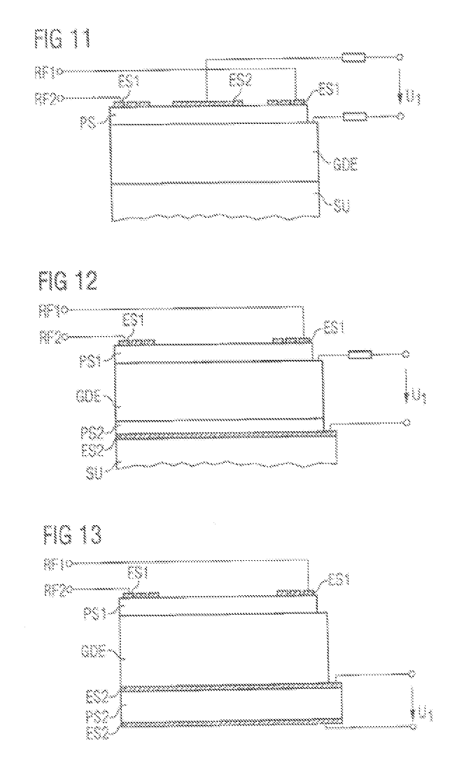

FIGS. 12 and 13, a tunable surface wave filter as resonator element, in which two control elements are provided;

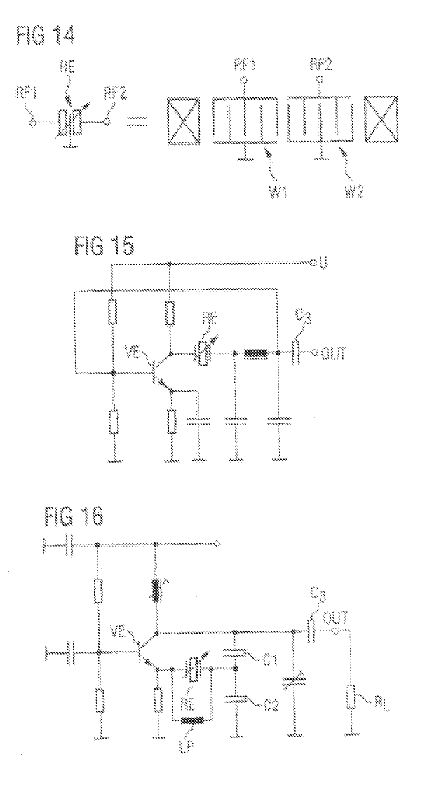

FIG. 14, as a resonator element, a tunable resonator filter constructed as a DMS filter;

FIG. 15, an oscillator with a resonator element in the collector branch of a transistor;

FIG. 16, an oscillator with a resonator element in the emitter branch of a transistor; and

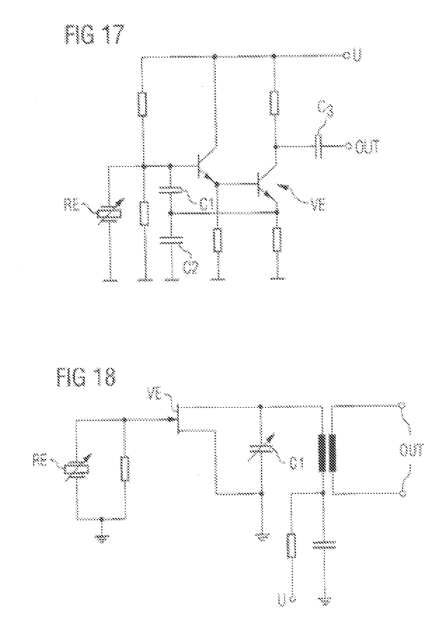

FIGS. 17 and 18, each an oscillator with a resonant circuit that is connected to ground at the input of the amplifier element.

FIG. 1 shows a known oscillator circuit (Pierce oscillator) with a resonator RE′ and an amplifier element VE. Along with resonator RE′, trimming capacitors C₁ and C₂ (e.g., varactors) are arranged in the feedback branch of the oscillator. The adjustment of the oscillator frequency is done with the aid of varactors C₁ and C₂. U is a control voltage for adjusting the operating point of the amplifier element (via an amplifier stage and a resistor). The generated high-frequency signal is picked off via an output OUT. The DC component of the signal is cut off via separation capacitor C₃.

FIG. 2A shows an oscillator according to the second embodiment of the invention. The resonant circuit in this case is arranged in the feedback branch of the amplifier element. The resonator element is arranged in the feedback branch of amplifier element VE. The resonator element here consists of a tunable resonator. The difference from FIG. 1 is that resonator element RE is itself a trimming element with which the resonant frequency can be adjusted. Capacitors C₁ and C₂, which are connected in series to one another and in parallel to the resonator element, are not tunable in this example. In a variant of the invention, capacitors C₁ and C₂ can also be tunable.

In this example, a control element not shown here, such as a control layer connected to resonator element RE, is formed; see the explanations for FIGS. 9-13.

FIG. 2B shows that the tunable resonator element RE according to the first preferred embodiment of the invention can be replaced by a switchable resonator bank T1. In FIG. 2B, several sub-branches electrically connected in parallel to one another are provided in the feedback branch. Resonator element RE is constructed as a resonator bank T1 with n resonators REⱼ, j=1 through n. Resonators REⱼ are each connected in series to an associated switch element Sⱼ. The respective series circuit of these elements is arranged in a sub-branch.

Among the multiple sub-branches, precisely one sub-branch, for instance, is switched into the resonant circuit at a given point in time.

A resonator bank T1 can also be available as a compact component with external contacts. In one variant of the invention, the resonator element (or its resonators REⱼ) is arranged in a compact component that also has other components such as switch elements Sⱼ. It is indicated in FIG. 2C that the individual switch elements Sⱼ can be replaced by a selector switch S. The selector switch can also be available as a compact component. Selector switch S can have several switch elements Sⱼ.

In the example shown in FIG. 2C, amplifier element VE is constructed as an operational amplifier. The resonant circuit comprises the selector switch, resonator element RE, as well as a series circuit of trimming capacitors C₁ and C₂ balanced relative to ground. Trimming capacitors C₁ and C₂ here constitute an (additional) trimming element, which is connected in parallel to resonator element RE.

FIG. 3A shows a block schematic of an oscillator with a field-effect transistor as the amplifier element, a resonator bank T₁ and individual switch elements Sⱼ, which are arranged in the sub-branches of the resonant circuit. In this case there is a voltage-controlled amplifier element. Switch elements Sⱼ can be alternatively be available as current-controlled switching elements (e.g., diodes).

Resonators REⱼ preferably have resonant frequencies fⱼ differing from one another. Preferably only one resonator is switched into the resonant circuit in a defined frequency range. Selecting between the frequency ranges is done by means of switch elements Sⱼ. The switch elements are controlled such that at least one switch element (preferably only one switch element) is switched through in this range. With only one conducting switch element, all other switch elements are open.

The oscillator frequency can be fine-tuned inside the given frequency range with the aid of trimming capacitors C₁ and C₂.

FIG. 3B shows one sub-branch of a resonant circuit with several sub-branches. Alongside resonator REⱼ and switch element Sⱼ, the sub-branch has a trimming capacitor Cⱼ. In this example, trimming capacitor Cⱼ is connected in series with the respective resonator REⱼ.

FIG. 4 shows the resonance curves of various resonators in a resonator bank. Resonance curve 1 is associated with first resonator REⱼ. Resonance curves 2 and 3 are associated, respectively with second and third resonator RE₂ and RE₃. In switching from the first to the second or third resonator, the transition between resonance curve 1 to resonance curve 2 or 3 takes place.

It is indicated in FIG. 5A that resonators REⱼ of a resonator bank T1 can each be tunable. It is also possible for only one resonator or a part of the resonators to be constructed tunably in a resonator bank.

In this case, the fine-tuning of the resonator frequency can be carried out in the respective tunable resonator. In principle, therefore, additional trimming elements are not necessary.

It is indicated in FIG. 5B that additional trimming capacitors can nevertheless be provided. It is also possible for resonator REⱼ in one sub-branch illustrated in FIG. 3B to be tunable, as is provided in the second embodiment of the invention.

An oscillator with an operational amplifier as amplifier element VE is shown in FIG. 6. A resonator element RE and matching networks AN1 and AN2 are arranged in the feedback branch of the amplifier element. In principle, the matching networks can be provided in a resonant circuit branch or in its sub-branches. It is also possible to forgo adapting networks AN1, AN2 in the example of FIG. 6.

The resonator element here is provided as a tunable resonator filter with at least two acoustically coupled component resonators (e.g., transducers). For instance, the tunable resonator filter can be constructed as a DMS filter operating with surface acoustic waves, as in FIG. 14. The resonator filter can be formed as resonator stack with coupled thin-film resonators.

The component resonators in this example are also electrically connected to one another. It is also possible for the component resonators of a thus-constructed resonator element RE to be coupled only acoustically to one another. In a resonator stack, the acoustic coupling can occur through a coupling layer arranged between two component resonators.

In the example of FIG. 7, switch elements Sⱼ are formed as voltage-controlled elements (field-effect transistors). Switch element Sⱼ is triggered by means of a control voltage Uⱼ.

It is indicated in FIG. 8 that the trimming capacitors in trimming element T2 can be constructed as capacitor banks C′₁ and C′₂. The capacitor banks are controlled, preferably digitally, via input IN. The capacitor banks are preferably each connected to ground for balancing. It is also possible, however, for the capacitors arranged in the capacitor bank not to be connected to ground.

A thin-film resonator is shown in cross section in FIG. 9. The resonator here is produced as a multilayer element on a substrate SU. It comprises a control layer GDE, above which a tightly contacting piezoelectric layer PS is formed, which is furnished on one side with a pair of HF electrodes ES1 for exciting a volume acoustic wave, and on the other, with a pair of control voltage electrodes ES2. The control layer is preferably a so-called GDE (Giant Delta E) layer, i.e., a layer that has a “giant delta E” effect.

GDE materials are materials that have an unusually large change in their modulus of elasticity under mechanical stress. A number of such materials from many different material classes have become known in recent times.

A large change of rigidity due to mechanical stresses is achieved, for instance, with certain metallic glasses, so-called met glasses, which mainly consist of the metals iron, nickel and cobalt. For instance, met glasses with the compositions Fe₈₁Si_{3.5}B_{13.5}C₂, FeCuNbSiB, Fe₄₀Ni₄₀P₁₄B₆, Fe₅₅Co₃₀B₁₅ or Fe₈₀ with Si and Cr have a large delta E effect. Such met glasses are known, for instance, under the trade name VITROVAC® 4040 from vacuum casting or under the designation Metglas® 2605 SC (FE₈₁Si_{3.5}B_{13.5}C₂).

In the advantageous embodiment shown in FIG. 9, the top electrode represents both one of the HF electrodes and one of the control voltage electrodes at the same time. The second HF electrode and the second control voltage electrode are arranged on piezoelectric layer PS on top of the control layer.

In another embodiment, second HF electrode ES1 can be arranged underneath piezoelectric layer PS. The second control voltage electrode of electrode pair ES2 can lie as a thin metallic film either above or below control layer GDE. The latter possibility is indicated in FIG. 9 by the optionally provided metal film ME. Another possibility is that the control layer replaces one of the HF electrodes or control voltage electrodes. The control voltage electrodes can continue to be arranged transverse to the piezoelectric layer.

The thicknesses of piezoelectric layer PS and control layer GDE are selected such that both layers lie within the penetration depth of the acoustic wave.

The thickness ratio of piezoelectric layer PS to control layer GDE within the range of the penetration depth is another adjustable parameter for the invented component. The greater the proportion of the control layer inside the penetration depth is, the greater is the tuning range over which the operating frequency or center frequency of the filter can be shifted. A larger proportion of piezoelectric layer PS inside the penetration depth, on the other hand, increases the coupling, and thus the bandwidth, of the filter. Depending on the desired properties of the component, the ratio is adjusted such that either a high degree of coupling or a high tunability is obtained relative to both properties.

The acoustically active part of the component can be separated from substrate SU by an acoustic mirror AS, which assures a one-hundred percent reflection of the acoustic wave back into the acoustically active part of the component.

Another possibility is for the control layer to represent a sub-layer of acoustic mirror AS. The important point here as well is that the control layer lie within the penetration range of the acoustic wave, so that in this embodiment in particular, the control layer is an upper sub-layer of the acoustic mirror. Thus a better tunability is achieved via the control layer.

It is also possible for the lower control or HF electrode to represent a sub-layer of acoustic mirror AS.

The varying voltage applied to the control electrodes is used for frequency tuning of the filter. In the above-mentioned embodiment from FIG. 9, piezoelectric layer PS takes on a double function as an excitation layer for exciting volume acoustic waves and as a tunable layer for generating a mechanical stress, which is transferred to the control layer and elicits a change in material rigidity. The latter in turn influences the propagation velocity of the acoustic wave and thus the center frequency of the filter.

FIG. 10 shows the cross section of another advantageous embodiment of a tunable thin-film resonator. Piezoelectric excitation layer PS1 lies between two HF electrodes ES1. The lower of these electrodes ES1 simultaneously represents a control voltage electrode ES2. Underneath it, a first control layer GDE is arranged, which in another possible embodiment can replace the latter-mentioned electrode if first control layer GDE is electrically conductive. Between layer GDE and the lower of the control voltage electrodes ES2 lies a second control layer PS2 (the piezoelectric tuning layer).

A tunable resonator operating with surface waves is shown in FIG. 11 in a schematic cross section.

The resonator comprises a control layer GDE, above which a tightly contacting piezoelectric layer PS is formed. Electrode structures ES1 are formed on the surface of piezoelectric layer PS. The acoustic waves generated by electrode structures ES1, such as interdigital transducers, have a penetration depth of roughly one-half wavelength into the multilayer structure. The thicknesses of piezoelectric layer PS and control layer GDE are selected such that both layers lie within the penetration range of the acoustic wave.

A first control voltage electrode ES2 is arranged on the upper side of piezoelectric layer PS, which carries acoustic structures such as interdigital transducers and reflectors. Electrically conductive control layer GDE serves as second control electrode ES2 in this embodiment.

In addition, the second control electrode can be arranged above or below control layer GDE.

In the embodiment shown in FIG. 11, piezoelectric layer PS serves both to excite surface acoustic waves and to control the electrical properties of underlying control layer GDE by means of mechanical stresses that appear as a result of the inverse piezoelectric effect when a varying control voltage is applied.

FIG. 12 shows, on the basis of a schematic cross section, an additional example of a resonator operating with surface acoustic waves, wherein first control layer GDE is arranged between piezoelectric excitation layer PS1 and piezoelectric tuning layer PS2 (second control layer). A control voltage electrode ES2 lies underneath tuning layer PS2. Second control electrode ES2 can be formed either as first control layer GDE or as an additional metal layer above or below first control layer GDE.

A tunable surface wave filter without a carrier substrate is shown in FIG. 13. The acoustic structures, such as interdigital transducers or reflectors, are situated on the upper side of piezoelectric excitation layer PS1. First control layer GDE is arranged between excitation layer PS1 and second control layer PS2. The latter is furnished on both sides with control voltage electrodes ES2.

An additional variation possibility is to form upper control voltage electrode ES2 as the first control layer.

FIG. 14 schematically shows the structure of a (tunable) DMS filter. Two transducers W1, W2 are arranged here side-by-side in an acoustic track and are acoustically coupled to one another. Transducers W1, W2 are arranged between two reflector structures. A first transducer W1 is connected to a first signal terminal RF1. A second transducer W2 is connected to a second signal terminal RF2 of the resonator filter. Both transducers are connected to ground.

A control layer, not shown in FIG. 14, can be designed according to the arrangements shown in FIGS. 11-13.

Additional possible configurations of an oscillator according to the invention are shown in FIGS. 15-18. Resonator element RE in FIG. 15 is arranged in the collector branch of a transistor. In FIG. 16, resonator element RE is arranged in the emitter path of a transistor. Resonator element RE in FIGS. 17 and 18 is connected to ground at the input of the amplifier element.

In FIG. 16, R_{L} stands for a load resistor. Resonator element RE is connected in parallel with an inductor L_{P}. Additional trimming elements (a trimming inductor and a trimming capacitor) other than tunable resonator element RE are also provided.

This invention is not limited to the embodiments, oscillator types (e.g., Pierce, Colpitts, Clapp oscillators) or number of illustrated elements presented above. The resonators (e.g., SAW, FBAR) can be temperature-compensated to increase frequency stability.

List of Reference Characters

RE Resonator element
RE₁ . . . REₙ Resonator
U Control voltage
U₁ . . . Uₙ Control voltage
S₁ . . . Sₙ Switch
S Selector switch
T1 Resonator bank
T2 Trimming element
VE Amplifier element
R Resistor for adjusting the operating voltage of an amplifier element
C₁, C₂ Capacitor
C₁′, C₂′ Digitally controlled capacitor bank
C₃ Separation capacitor
1 Resonance curve (frequency response of the admittance) of the resonator bank with the first resonator switched in
2 Resonance curve (frequency response of the admittance) of the resonator bank with the second resonator switched in
3 Resonance curve (frequency response of the admittance) of the resonator bank with the third resonator switched in
AN1, AN2 Matching network
OUT Output
RF1, RF2 Terminals of the resonator
PS, PS1, PS2 Piezoelectric layer
PS′, PS″ Additional piezoelectric layer
ES1 First electrode
ES2 Second electrode
GDE (First) control electrode
ME Metal layer
SU Carrier substrate
AS Acoustic mirror
W1 First transducer
W2 Second transducer

1. An oscillator comprising:
a resonator element comprising at least one resonator; and
a control element for adjusting a resonant frequency of the resonator element among a plurality of different values.

2. The oscillator of claim 1, further comprising:
an amplifier element; and
a resonant circuit associated with the amplifier element, the resonator element being in the resonant circuit.

3. The oscillator of claim 2, wherein the resonator element comprises a resonator bank comprised of resonators;
wherein the resonant circuit comprises sub-branches in parallel;
wherein a resonator is in each sub-branch; and
wherein the control element comprises a selector switch for selecting among the sub-branches.

4. The oscillator of claim 3, wherein the control element comprises switches; and
wherein the switch is in each sub-branch.

5. The oscillator of claim 3, wherein at least one of the resonators has a resonant frequency that is tunable.

6. The oscillator of claim 3, wherein each of the resonators has a resonant frequency that is tunable.

7. The oscillator of claim 3, wherein at least two of the resonators have different resonant frequencies.

8. The oscillator of claim 4, wherein at least one sub-branch is switched into the oscillator circuit at a given point in time.

9. The oscillator of claim 1, wherein the at least one resonator comprises at least one dielectric resonator.

10. The oscillator of claim 1, wherein the at least one resonator comprises at least one LC resonator or at least one strip-line resonator.

11. The oscillator of claim 1, wherein the at least one resonator comprises at least one micromechanical resonator.

12. The oscillator of claim 1, wherein the at least one resonator element comprises at least one electroacoustic resonator.

13. The oscillator of claim 12, wherein the at least one resonator comprises at least one piezoelectric layer; and
wherein the control element comprises a control layer that is in contact with the at least one piezoelectric layer; and
wherein, under mechanical stress, the control layer influences a propagation velocity of an acoustic wave in the at least one piezoelectric layer.

14. The oscillator of claim 12, wherein the at least one resonator comprises at least one piezoelectric layer;
wherein the control element comprises a first control layer and a second control layer, the first and second control layers forming a composite; and
wherein the second control layer comprises an additional piezoelectric layer for producing mechanical stress in first control layer in order to influence a propagation velocity of an acoustic wave in the piezoelectric layer.

15. The oscillator of claim 13, wherein the control layer has a giant delta effect under stress.

16. The oscillator of claim 13, wherein the mechanical stress is generated by a control voltage.

17. The oscillator of claim 13, further comprising:
an additional control element for switching between sub-branches of a resonant circuit comprised of the at least one resonator.

18. The oscillator of claim 12, wherein the at least one resonator comprises a thin-film resonator operating with bulk acoustic waves.

19. The oscillator of claim 18, wherein the at least one resonator comprises a resonator stack comprising component resonators arranged in a stack.

20. The oscillator of claim 12, wherein the at least one resonator operates with surface acoustic waves.

21. The oscillator of claim 20, wherein the at least one resonator comprises transducers that are longitudinally coupled to each other acoustically and that are arranged in an acoustic track.

22. The oscillator of claim 2, further comprising:
a trimming element in the resonant circuit.

23. The oscillator of claim 22, wherein the trimming element comprises a trimming capacitor or a trimming inductor.

24. The oscillator of claim 22, wherein the trimming element is in parallel with the resonator element.

25. The oscillator of claim 22, wherein the trimming element is in series with the at least one resonator.
